(19) United States
(12) Patent Application Publication
(10) Pub. No.: US 2019/0305036 A1
(43) Pub. Date: Oct. 3, 2019

(54) MICRO LED SEMI-FINISHED PRODUCT MODULE

(71) Applicant: POINT ENGINEERING CO., LTD., Asan (KR)

(72) Inventors: Bum Mo AHN, Suwon (KR); Seung Ho PARK, Hwaseong (KR)

(21) Appl. No.: 16/370,749

(22) Filed: Mar. 29, 2019

(30) Foreign Application Priority Data
Mar. 30, 2018 (KR) 10-2018-0036960

(51) Int. Cl. H01L 27/15; H01L 33/62

(52) U.S. Cl. CPC H01L 27/156; H01L 33/325; H01L 33/62

(57) ABSTRACT

The present invention relates to a micro LED semi-finished product module and, more specifically, to a micro LED semi-finished product module being manufactured to be individually bonded to a second substrate and being modularized by mounting multiple micro LEDs on a first substrate. Accordingly, it possible to manufacture a large display using micro LEDs and it is easy to manage a defect rate.

### CROSS REFERENCE TO RELATED APPLICATION

The present application claims priority to Korean Patent Application No. 10-2018-0036960, filed Mar. 30, 2018, the entire contents of which is incorporated herein for all purposes by this reference.

### BACKGROUND OF THE INVENTION

### Field of the Invention

The present invention relates to a micro light-emitting diode (micro LED) semi-finished product module.

### Description of the Related Art

Currently, the display market is still dominated by LCDs, but OLEDs are quickly replacing LCDs and emerging as mainstream products. In a current situation where display makers are rushing to participate in the OLED market, micro light-emitting diode (hereinafter, referred to as micro LED) displays have emerged as another next generation display. Liquid crystal and organic materials are the core materials of LCDs and OLEDs, respectively, whereas the micro LED display uses 1 μm to 100 μm of an LED chip itself as light emitting material.

Since the term “micro LED” emerged in a patent “MICRO-LED ARRAYS WITH ENHANCED LIGHT EXTRACTION” in 1999 (Korean Patent No. 10-0731673, hereinafter referred to as ‘Related Art 1’) disclosed by Cree Inc., related research papers based thereon were subsequently published. In order to apply the micro LED to a display, it is necessary to develop a customized microchip based on a flexible material and/or flexible device using a micro LED device, and techniques of transferring the micrometer-sized LED chip and mounting the LED chip on a display pixel electrode are required.

In order to make a micro LED TV having a display with 4K resolution, generally 25 million micro LEDs are transferred to a circuit board. Even if 10,000 micro LEDs can be transferred to a circuit board in an hour, it takes 100 days to make one TV.

Furthermore, even if the transfer yield is high, there is a problem in the case the micro LEDs are collectively transferred to a circuit board having a large area. Some of the micro LEDs may be defective when manufactured on a growth substrate, and in this case, the defective micro LEDs are required to be replaced individually on the circuit board.

### Documents of Related Art

(Patent Document 1) Korean Patent No. 10-0731673

### SUMMARY OF THE INVENTION

Accordingly, the present invention has been made keeping in mind the above problems occurring in the related art, and an objective of the present invention to provide a micro LED semi-finished product module enabling to manufacture a large display using micro LEDs and to manage a defect rate easily.

In order to achieve the above objective, there is provided a micro LED semi-finished product module manufactured to be individually bonded to a wiring board. The semi-finished product module is modularized by mounting multiple micro LEDs on a circuit board.

In addition, the semi-finished product module may be manufactured such that each of the micro LEDs of each semi-finished product module is individually driven by the wiring board to which the each micro LED semi-finished product module is bonded.

The semi-finished product module may be manufactured such that each semi-finished product module is individually driven by the wiring board to which the each micro LED semi-finished product module is bonded.

The semi-finished product module may be manufactured such that all of the micro LEDs are driven by the wiring board to which the micro LED semi-finished product module is bonded.

In addition, the circuit board may be provided with a thin-film transistor (TFT) circuit.

In order to achieve the above objective, there is provided a micro LED semi-finished product module manufactured to be individually bonded to a circuit board. The semi-finished product module is modularized by mounting multiple micro LEDs on an anisotropic conductive film.

In order to achieve the above objective, there is provided a micro LED semi-finished product module manufactured to be individually bonded to a circuit board. The semi-finished product module is modularized by mounting multiple micro LEDs on an anisotropic conductive anodic oxide film.

In addition, the semi-finished product module may have a one-dimensional array in which a red micro LED, a green micro LED, and a blue micro LED are arranged to form unit pixels, wherein a unit pixel positioned at the first row and the Mth column has the same arrangement order as a unit pixel positioned at the first row and the first column does, and an arrangement order of a unit pixel positioned at the Nth row and the first column and an arrangement order of a unit pixel positioned at the Nth row and the Mth column are the arrangement order of the unit pixel positioned at the first row and the second column, wherein M is an integer of 2 or more, and N is a multiple of 3.

The semi-finished product module may have a two-dimensional array in which a red micro LED, a green micro LED, and a blue micro LED are arranged to form unit pixels, and the unit pixels are arranged in an N by M matrix.

In addition, a distance between the micro LEDs located at the outermost edge of the semi-finished product module may be equal to or less than half of a distance between the micro LEDs.

As described above, a micro LED semi-finished product module according to the present invention is possible to enable to manufacture a large display using micro LEDs and to manage a defect rate easily.

### BRIEF DESCRIPTION OF THE DRAWINGS

The above and other objects, features and other advantages of the present invention will be more clearly understood from the following detailed description when taken in conjunction with the accompanying drawings, in which:

FIG. 1 is a view illustrating each micro LED semi-finished product module fabricated on a first substrate according to an embodiment of the present invention and the micro LED semi-finished product modules assembled on a second substrate;

FIG. 2 is a view illustrating micro LEDs fabricated on a growth substrate before being transferred to the micro LED semi-finished product module of the embodiment of the present invention;

FIG. 3 is a view illustrating the micro LED semi-finished product module according to the embodiment of the present invention;

FIGS. 4A to 4C are views illustrating the micro LED semi-finished product modules manufactured in FIG. 3 being assembled on a second substrate;

FIG. 5 is a view illustrating a micro LED semi-finished product module according to an embodiment of the present invention;

FIGS. 6A to 6C are views illustrating the micro LED semi-finished product modules manufactured in FIG. 5 being assembled on a second substrate; and

FIGS. 7 to 11 are views each illustrating an arrangement of unit pixels of a micro LED semi-finished product module according to an embodiment of the present invention.

### DETAILED DESCRIPTION OF THE INVENTION

Contents of the description below merely exemplify the principle of the invention. Therefore, those of ordinary skill in the art may implement the theory of the invention and invent various apparatuses which are included within the concept and the scope of the invention even though it is not clearly explained or illustrated in the description. Furthermore, in principle, all the conditional terms and embodiments listed in this description are clearly intended for the purpose of understanding the concept of the invention, and one should understand that this invention is not limited to the exemplary embodiments and the conditions.

The above described objectives, features, and advantages will be more apparent through the following detailed description related to the accompanying drawings, and thus those of ordinary skill in the art may easily implement the technical spirit of the invention.

The embodiments of the present invention are described with reference to cross-sectional views and/or perspective views which schematically illustrate ideal embodiments of the present invention. For explicit and convenient description of the technical content, sizes or thicknesses of films and regions and diameters of holes in the figures may be exaggerated. Therefore, variations from the shapes of the illustrations as a result, for example, of manufacturing techniques and/or tolerances, are to be expected. In addition, a limited number of multiple micro LEDs are illustrated in the drawings. Thus, the embodiments should not be construed as limited to the particular shapes of regions illustrated herein but are to include deviations in shapes that result, for example, from manufacturing.

Wherever possible, the same reference numerals will be used throughout different embodiments and the description to refer to the same or like elements or parts. In addition, the configuration and operation already described in other embodiments will be omitted for convenience.

Hereinafter, embodiments of the present invention will be described in detail with reference to the accompanying drawings.

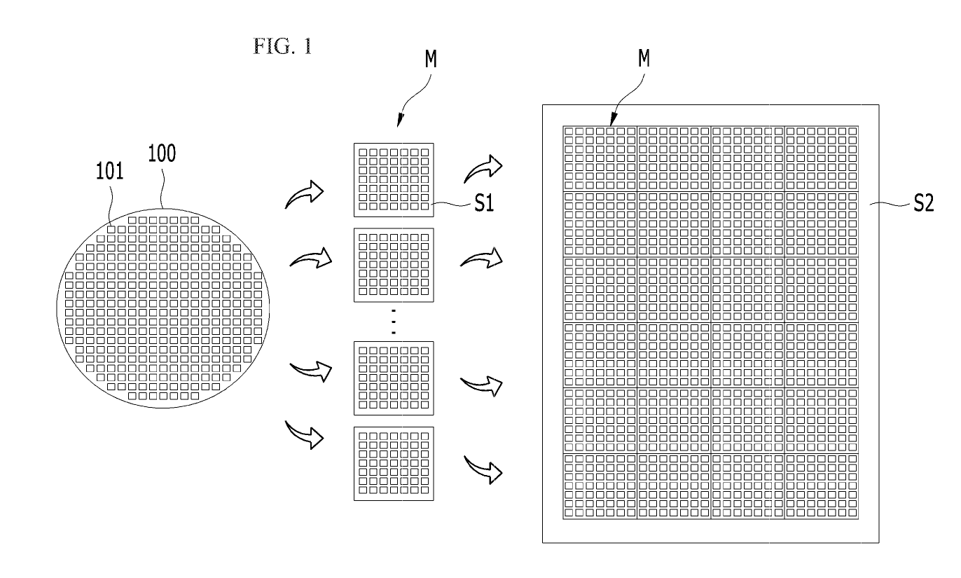

FIG. 1 is a view illustrating each micro LED semi-finished product module fabricated according to an embodiment of the present invention and the micro LED semi-finished product modules mounted on a large display.

Referring to FIG. 1, micro LED 100s fabricated on a growth substrate 101 are transferred to a first substrate S1 to be a semi-finished product module M according to an embodiment of the present invention. Here, the first substrate S1 to be described later may be embodied by a circuit board 300, an anisotropic conductive film (ACF) 480, or an anisotropic conductive anodic oxide film. Multiple semi-finished product modules M are fabricated individually and mounted on a second substrate S2 to constitute a large display whereby it is possible to realize a bezel-less large display. Here, the second substrate S2 may be embodied by a circuit board.

In addition, since each of the semi-finished product modules has a relatively small number of micro LEDs 100 mounted thereon, inspecting whether products are defective or not is simple, and a repair based on the inspection is easily performed. As a result, it is possible to mount the semi-finished product module M composed only of the fully functional micro LEDs 100 on a large display, thereby improving the production yield of the large display and shortening the manufacturing time.

Hereinafter, the micro LED semi-finished product module of the present invention will be described in detail.

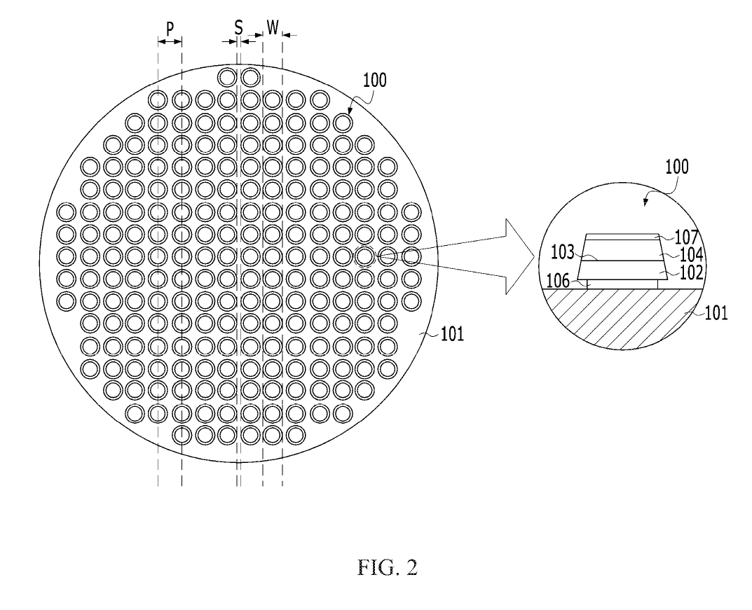

FIG. 2 is a view illustrating the multiple micro LEDs 100 to be transferred to the micro LED semi-finished product module of the embodiment of the present invention. Although the micro LEDs 100 illustrated in FIG. 2 have a circular cross-section, the cross-sectional shape of the micro LEDs 100 is merely an example, and is not limited thereto. Thus, the micro LEDs 100 may have a quadrangular cross-section as illustrated in FIG. 1.

The micro LEDs 100 are fabricated and disposed on the growth substrate 101.

The growth substrate 101 may be formed into a conductive substrate or an insulating substrate. For example, the growth substrate 101 is formed of at least one selected from among the group consisting of sapphire, SiC, Si, GaAs, GaN, ZnO, Si, GaP, InP, Ge, and Ga₂O₃.

Each of the micro LEDs 100 includes: a first semiconductor layer 102; a second semiconductor layer 104; an active layer 103 provided between the first semiconductor layer 102 and the second semiconductor layer 104; a first contact electrode 106; and a second contact electrode 107.

The first semiconductor layer 102, the active layer 103, and the second semiconductor layer 104 may be formed by performing metalorganic chemical vapor deposition (MOCVD), chemical vapor deposition (CVD), plasma-enhanced chemical vapor deposition (PECVD), molecular-beam epitaxy (MBE), hydride vapor phase epitaxy (HVPE), or the like.

The first semiconductor layer 102 may be implemented, for example, as a p-type semiconductor layer. A p-type semiconductor layer may be a semiconductor material having a composition formula of InₓAl_{y}Ga_{1-x-y}N (0≤x≤1, 0≤y≤1, 0≤x+y≤1), for example, GaN, AlN, AlGaN, InGaN, InN, InAlGaN, AlInN, and the like, and the layer may be doped with a p-type dopant such as Mg, Zn, Ca, Sr, and Ba.

The second semiconductor layer 104 may be implemented, for example, as an n-type semiconductor layer. An n-type semiconductor layer may be a semiconductor material having a composition formula of InₓAl_{y}Ga_{1-x-y}N (0≤x≤1, 0≤y≤1, 0≤x+y≤1), for example, GaN, AlN, AlGaN, InGaN, InNInAlGaN, AlInN, and the like, and the layer may be doped with an n-type dopant such as Si, Ge, and Sn.

However, the present invention is not limited to this.

The first semiconductor layer 102 may include an n-type semiconductor layer, and the second semiconductor layer 104 may include a p-type semiconductor layer.

The active layer 103 is a region where electrons and holes are recombined. As the electrons and the holes are recombined, the active layer 103 transits to a low energy level and generates light having a wavelength corresponding thereto. The active layer 103 may be formed of a semiconductor material having a composition formula of InxAl_{y}Ga_{1-x-y}N (0≤x≤1, 0≤y≤1, 0≤x+y≤1) and may have a single quantum well structure or a multi quantum well (MQW) structure. In addition, the active layer 103 may have a quantum wire structure or a quantum dot structure.

The first semiconductor layer 102 may be provided with the first contact electrode 106, and the second semiconductor layer 104 may be provided with the second contact electrode 107. The first contact electrode 106 and/or the second contact electrode 107 may include one or more layers and may be made of various conductive materials including a metal, conductive oxide, and conductive polymer.

The micro LEDs 100 formed on the growth substrate 101 are separated into individual pieces by etching. Then, it is possible to separate the individual micro LEDs 100 from the growth substrate 101 by a laser lift-off process.

In FIG. 2, the letter ‘P’ denotes a pitch distance between the micro LEDs 100, ‘S’ denotes a separation distance between the micro LEDs 100, and ‘W’ denotes a width of each micro LED 100.

The micro LED semi-finished product module M according to the embodiment of the present invention is provided with the first substrate S1 on which the micro LEDs 100 are mounted. The micro LED semi-finished product module M according to the embodiment of the present invention is manufactured to be individually bonded to a wiring board S2. The semi-finished product module M is modularized by mounting the multiple micro LEDs 100 on the first substrate S1. Here, the first substrate S1 may be embodied by the circuit board 300, the ACF 480, or the anisotropic conductive anodic oxide film (not illustrated).

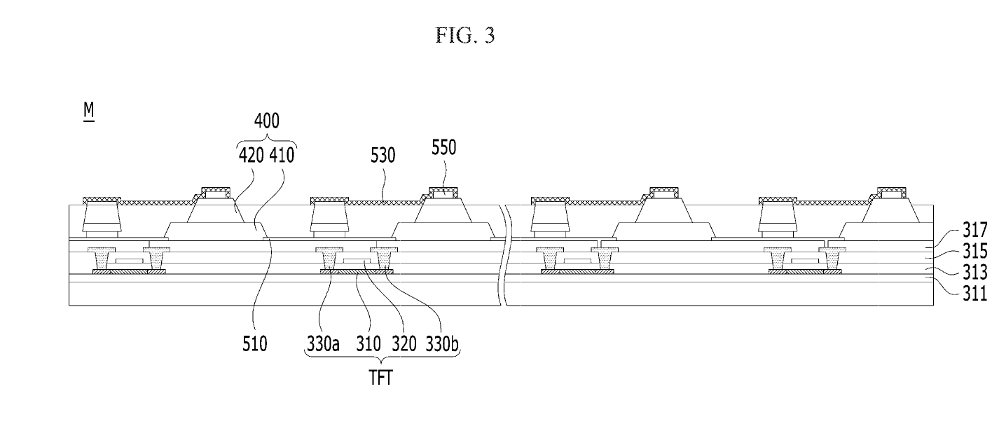

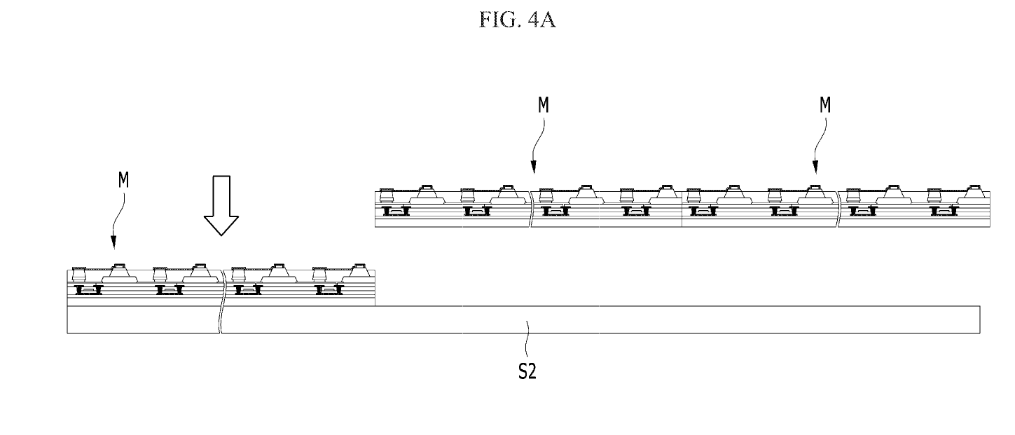

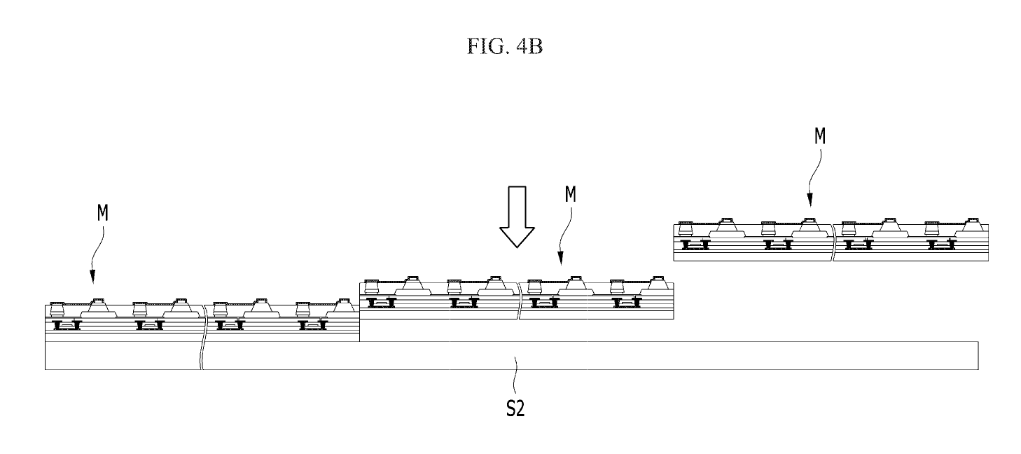

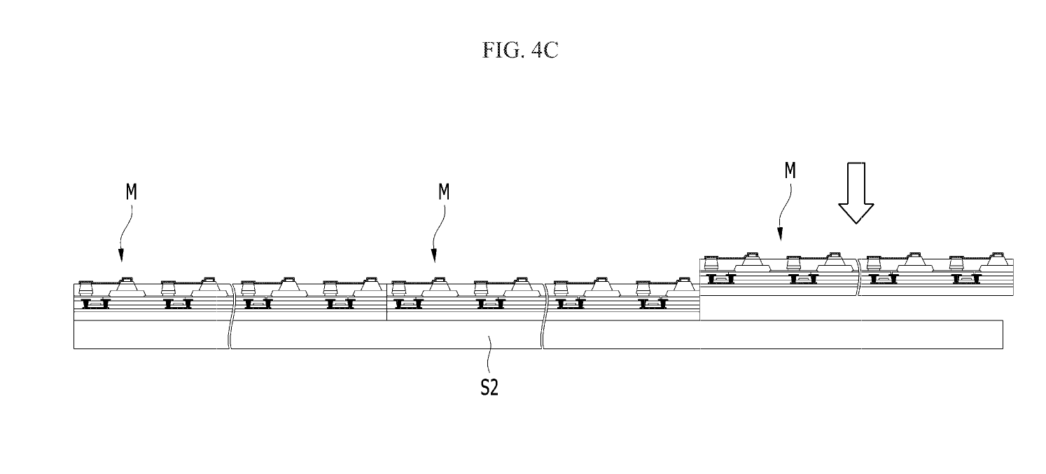

FIGS. 3, 4A, 4B, and 4C are views illustrating an embodiment in which the first substrate S1 is embodied by the circuit board 300. In other words, the micro LED semi-finished product modules M illustrated in FIGS. 3, 4A, 4B, and 4C are manufactured to be individually bonded to a wiring board and are modularized by mounting the multiple micro LEDs 100 on the circuit board 300.

Referring to FIG. 3, the circuit board 300 may include various materials. For example, the circuit board 300 may be made of a transparent glass material having SiO₂ as a main component. However, materials of the circuit board 300 are not limited to this, and the circuit board 300 may be made of a transparent plastic material and have solubility. The plastic material may be an organic insulating substance selected from the group consisting of polyethersulfone (PES), polyacrylate (PAR), polyetherimide (PEI), polyethylene naphthalate (PEN), polyethylene terephthalate (PET), polyphenylene sulfide (PPS), polyallylate, polyimide, polycarbonate (PC), cellulose triacetate (TAC), and cellulose acetate propionate (CAP).

In the case of a bottom emission type in which an image is implemented in a direction of the circuit board 300, the circuit board 300 is required to be made of a transparent material. However, in the case of a top emission type in which an image is implemented in a direction opposite to the circuit board 300, the circuit board 300 is not required to be made of a transparent material. In this case, the circuit board 300 may be made of metal.

In the case of forming the circuit board 300 using metal, the circuit board 300 may be made of at least one metal selected from among the group consisting of iron, chromium, manganese, nickel, titanium, molybdenum, stainless steel (SUS), Invar, Inconel, and Kovar, but is not limited thereto.

The circuit board 300 may include a buffer layer 311. The buffer layer 311 provides a flat surface and blocks foreign matter or moisture from penetrating therethrough. For example, the buffer layer 311 may be made of an inorganic substance such as silicon oxide, silicon nitride, silicon oxynitride, aluminum oxide, aluminum nitride, titanium oxide, and titanium nitride, or an organic substance such as polyimide, polyester, and acrylic. Alternatively, the buffer layer 311 may be formed in a stacked manner with the exemplified substances.

The circuit board 300 has a thin-film transistor (TFT) circuit. A thin-film transistor (TFT) may include an active layer 310, a gate electrode 320, a source electrode 330a, and a drain electrode 330b.

Hereinafter, a case where a TFT is a top gate type in which the active layer 310, the gate electrode 320, the source electrode 330a, and the drain electrode 330b are sequentially formed will be described. However, the present embodiment is not limited thereto, and various types of TFTs such as a bottom gate TFT may be employed.

The active layer 310 may contain a semiconductor material, such as amorphous silicon and polycrystalline silicon. However, the present embodiment is not limited thereto, and the active layer 310 may contain various materials. As an alternative embodiment, the active layer 310 may contain an organic semiconductor material or the like.

As another alternative embodiment, the active layer 310 may contain an oxide semiconductor material. For example, the active layer 310 may contain an oxide of a metal element selected from Groups 12, 13, and 14 elements such as zinc (Zn), indium (In), gallium (Ga), tin (Sn), cadmium (Cd), and germanium (Ge), and a combination thereof.

A gate dielectric layer 313 is formed on the active layer 310. The gate dielectric layer 313 serves to isolate the active layer 310 and the gate electrode 320. The gate dielectric layer 313 may be formed into a multilayer or a single layer of a film made of an inorganic substance such as silicon oxide and/or silicon nitride.

The gate electrode 320 is provided on the gate dielectric layer 313. The gate electrode 320 may be connected to a gate line (not illustrated) applying an on/off signal to the TFT.

The gate electrode 320 may be made of a low-resistivity metal. In consideration of adhesion with an adjacent layer, surface flatness of layers to be stacked, and processability, the gate electrode 320 may be formed into a multilayer or a single layer, which is made of at least one metal selected from among the group consisting of aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu).

An interlayer dielectric film 315 is provided on the gate electrode 320. The interlayer dielectric film 315 isolates the source electrode 330a and the drain electrode 330b, and the gate electrode 320. The interlayer dielectric film 315 may be formed into a multilayer or single layer of a film made of an inorganic substance. For example, the inorganic substance may be a metal oxide or a metal nitride. Specifically, the inorganic substance may include silicon dioxide (SiO₂), silicon nitrides (SiNₓ), silicon oxynitride (SiON), aluminum oxide (Al₂O₃), titanium dioxide (TiO₂), tantalum pentoxide (Ta₂O₅), hafnium dioxide (HfO₂), or zirconium dioxide (ZrO₂).

The source electrode 330a and the drain electrode 330b are provided on the interlayer dielectric film 315. The source electrode 330a and the drain electrode 330b may be formed into a multilayer or a single layer, which is made of at least one metal selected from among the group consisting of aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu). The source electrode 330a and the drain electrode 330b are electrically connected to a source region and a drain region of the active layer 310, respectively.

A planarization layer 317 is provided on the TFT. The planarization layer 317 is configured to cover the TFT, thereby eliminating steps caused by the TFT and planarizing the top surface. The planarization layer 317 may be formed into a single layer or a multilayer of a film made of an organic substance. The organic substance may include a general-purpose polymer such as polymethyl methacrylate (PMMA) and polystyrene (PS); a polymer derivative having phenols; polyacrylates; polyimides, poly(aryl ethers); polyamides; fluoropolymers; poly-p-xylenes; and polyvinyl alcohols; and a combination thereof. In addition, the planarization layer 317 may be formed into a multi-stack including an inorganic insulating layer and an organic insulating layer.

A first electrode 510 is provided on the planarization layer 317. The first electrode 350 may be electrically connected to the TFT. Specifically, the first electrode 350 may be electrically connected to the drain electrode 330b through a contact hole formed in the planarization layer 317. The first electrode 350 may have various shapes. For example, the first electrode 350 may be patterned in an island layout. A bank layer 400 defining a pixel region may be disposed on the planarization layer 317. The bank layer 400 may include a recess where the micro LED 100 will be received. The bank layer 400 may include, for example, a first bank layer 410 defining the recess. A height of the first bank layer 340 may be determined by a height and viewing angle of the micro LED 100. A size (width) of the recess may be determined by resolution, pixel density, and the like, of a display device. In an embodiment, the height of the micro LED 100 may be greater than the height of the first bank layer 340. The recess may have a quadrangular cross section, but is not limited to this. The recess may have various cross-sectional shapes, such as polygonal, rectangular, circular, conical, elliptical, and triangular.

The bank layer 400 may further include a second bank layer 420 on the first bank layer 340. The first bank layer 340 and the second bank layer 341 have a step difference, and a width of the second bank layer 341 may be smaller than the width of the first bank layer 340. A conductive layer 550 may be disposed on the second bank layer 341. The conductive layer 355 may be disposed in a direction parallel to a data line or a scan line, and may be electrically connected to a second electrode 353. However, the present invention is not limited thereto. The second bank layer 341 may be omitted, and the conductive layer 355 may be disposed on the first bank layer 340. Alternatively, the second bank layer 341 and the conductive layer 550 may be omitted, and the second electrode 353 may be formed over the entire substrate such that the second electrode 353 serves as a shared electrode that the pixels (P) share. The first bank layer 340 and the second bank layer 341 may include a material absorbing at least a part of light, a light reflective material, or a light scattering material. The first bank layer 340 and the second bank layer 341 may include an insulating material that is translucent or opaque to visible light (e.g., light in a wavelength range of 380 nm to 750 nm).

For example, the first bank layer 340 and the second bank layer 341 may be formed of a thermoplastic such as polycarbonate (PC), polyethylene terephthalate (PET), polyethersulfone, polyvinyl butyral, polyphenylene ether, polyamide, polyetherimide, polynorbornene, poly(methyl methacrylate) resin, and cyclic polyolefin resin, a thermosetting plastic such as epoxy resin, phenolic resin, urethane resin, acrylic resin, vinyl ester resin, polyimide resin, urea resin, and melamine resin, or an organic insulating substance such as polystyrene, polyacrylonitrile, and polycarbonate, but are not limited thereto.

As another example, the first bank layer 340 and the second bank layer 341 may be formed of an inorganic insulating substance such as inorganic oxide and inorganic nitride including SiOₓ, SiNₓ, SiNxO_{y}, AlOₓ, TiOₓ, TaOₓ, and ZnOₓ, but are not limited thereto. In an embodiment, the first bank layer 340 and the second bank layer 341 may be formed of an opaque material such as a material of a black matrix. A material of the insulating black matrix may include a resin or a paste including organic resin, glass paste, and black pigment; metal particles such as nickel, aluminum, molybdenum, and alloys thereof; metal oxide particles (e.g., chromium oxide); metal nitride particles (e.g., chromium nitride), or the like. In an alternate embodiment, the first bank layer 340 and the second bank layer 341 may be a distributed Bragg reflector (DBR) having high reflectivity or a mirror reflector made of metal.

The micro LED 100 is disposed in the recess. The micro LED 100 may be electrically connected to the first electrode 350 at the recess.

The micro LED 100 emits light having wavelengths of different colors such as red, green, blue, white, and the like. With the micro LED 100, it is possible to realize white light by using fluorescent materials or by combining colors. The micro LED 100 has a size of 1 μm to 100 μm. The micro LEDs 100 are picked up from the growth substrate 101 individually or collectively by a transfer head, transferred to the circuit board 300, and received in the recess of the circuit board 300.

The micro LED 100 includes a p-n diode, the first contact electrode 106 disposed on one side of the p-n diode, and the second contact electrode 107 disposed on the opposite side of the first contact electrode 106. The first contact electrode 106 may be connected to the first electrode 350, and the second contact electrode 107 may be connected to the second electrode 353.

The first electrode 350 may include: a reflective layer made of Ag, Mg, Al, Pt, Pd, Au, Ni, Nd, Ir, Cr, or a compound thereof; and a transparent or translucent electrode layer provided on the reflective layer. The transparent or translucent electrode layer may be made of at least one selected from among the group consisting of indium tin oxide (ITO), indium zinc oxide (IZO), zinc oxide (ZnO), indium oxide (In₂O₃), indium gallium oxide (IGO), and aluminum zinc oxide (AZO).

A passivation layer 520 surrounds the micro LED 100 in the recess. The passivation layer 520 covers the recess and the first electrode 350 by filling a space between the bank layer 400 and the micro LED 100. The passivation layer 520 may be made of an organic insulating substance. For example, the passivation layer 520 may be made of acrylic, poly (methyl methacrylate) (PMMA), benzocyclobutene (BCB), polyimide, acrylate, epoxy, and polyester, but is not limited thereto.

The passivation layer 520 is formed to have a height not covering an upper portion of the micro LED 100, for example, a height not covering the second contact electrode 107, whereby the second contact electrode 107 is exposed. The second electrode 353 may be formed on the passivation layer 520 electrically connected to the exposed second contact electrode 107 of the micro LED 100.

The second electrode 353 may be disposed on the micro LED 100 and the passivation layer 520. The second electrode 353 may be formed of a transparent conductive material such as ITO, IZO, ZnO, and In₂O₃.

FIGS. 4A to 4C are views illustrating a process of bonding the micro LED semi-finished product modules M illustrated in FIG. 3 to the second substrate S2. As illustrated in FIGS. 4A to 4C, the multiple semi-finished product modules M may be bonded to the second substrate S2 individually.

Here, the second substrate S2 may be embodied by a wiring board enabling to individually drive each of the micro LEDs 100 of the semi-finished product module M. That is, the semi-finished product modules M are manufactured such that the micro LEDs 100 of each semi-finished product module M are individually driven by the wiring board S2 to which the semi-finished product modules M are bonded. In other words, the wiring board is provided with driving circuits in a predetermined number corresponding to the number of the micro LEDs 100 such that it is possible to drive the micro LEDs 100 individually.

Alternatively, the second substrate S2 may be embodied by a wiring board enabling to drive each of the semi-finished product modules M individually. That is, the semi-finished product modules M are manufactured such that the semi-finished product modules M are individually driven by the wiring board S2 to which the semi-finished product modules M are bonded. In other words, the wiring board is provided with driving circuits in a predetermined number corresponding to the number of the semi-finished product modules M such that it is possible to drive the semi-finished product modules M individually.

In addition, alternatively, the second substrate S2 may be embodied by a wiring board enabling to drive all of the micro LEDs 100 of the semi-finished product modules M together. That is, the semi-finished product modules M are manufactured such that all of the micro LEDs 100 of the semi-finished product modules M are driven by the wiring board S2 to which the semi-finished product modules M are bonded. In other words, irrespective of the number of semi-finished product modules M and the number of micro LEDs 100, the wiring board is capable of driving all of the micro LEDs 100 together.

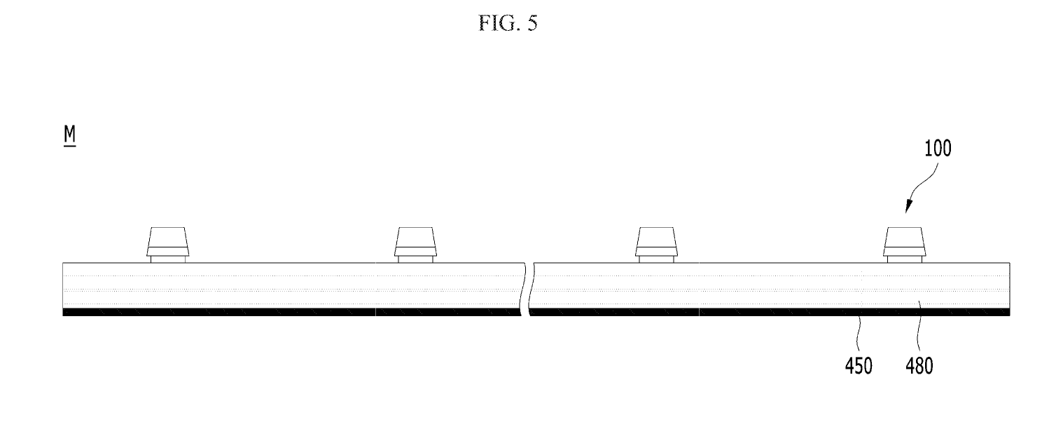

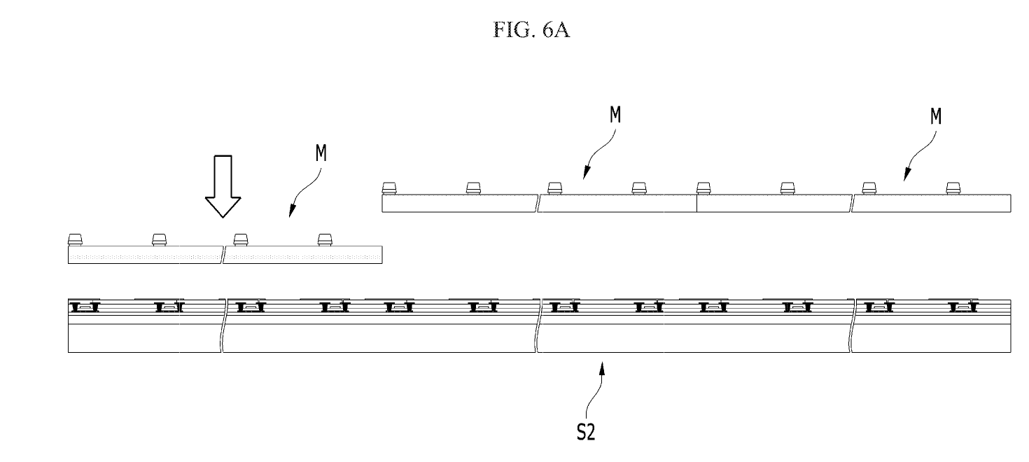

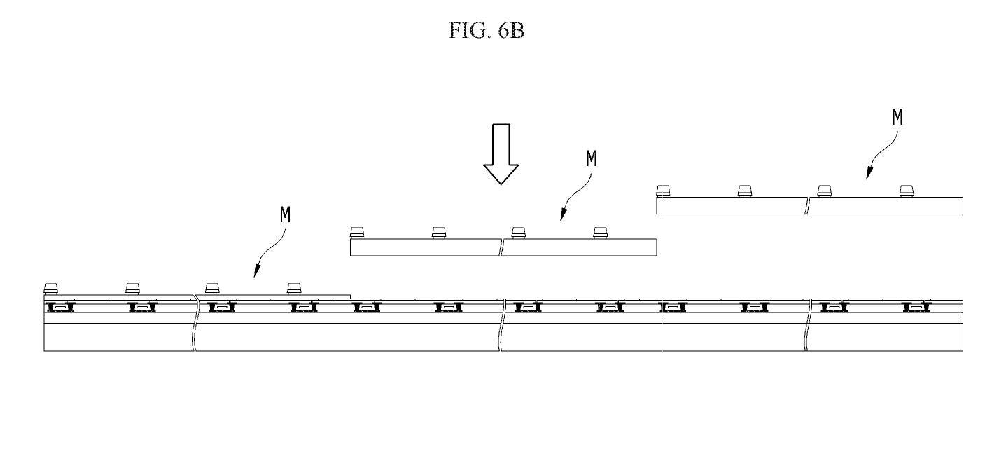

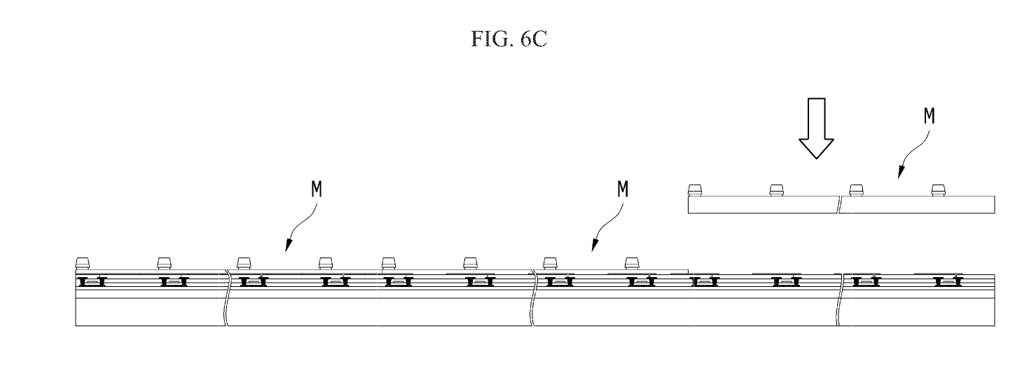

FIGS. 5, 6A, 6B, and 6C are views illustrating an embodiment in which the first substrate S1 is embodied by the ACF 480. In other words, a micro LED semi-finished product modules M illustrated in FIGS. 5, 6A, 6B, and 6C are manufactured to be individually bonded to the second substrate S2, and are modularized by mounting the multiple micro LEDs 100 on the ACF 480. Here, the second substrate S2 may be embodied by a circuit board.

Referring to FIG. 5, the ACF 480 is formed of multiple particles in which respective conductive cores are coated with an insulating film. When pressure or heat is applied to the ACF 480, the insulating film is destroyed at a region to which the pressure or heat is applied such that the region of the ACF 480 is electrically connected via the exposed core of the ACF 480.

A release film 450 may be further provided below the ACF 480. The release film 450 is attached a lower surface of the ACF 480 to prevent particles from adhering to the lower surface of the ACF 480. The release film 450 is attached in a manner being easily removable for bonding the semi-finished product module M to the second substrate S2.

FIGS. 6A to 6C are views illustrating a process of bonding the micro LED semi-finished product modules M illustrated in FIG. 5 to the second substrate S2. As illustrated in FIGS. 6A to 6C, the multiple semi-finished product modules M may be bonded to the second substrate S2 individually.

Before mounting the semi-finished product modules M on the second substrate S2, the release film 450 attached below the ACF 480 is separated therefrom. Next, the micro LEDs 100 are thermally pressed from the top to the bottom to electrically connect the micro LEDs 100 and individual electrodes formed on the second substrate S2 with each other. Accordingly, only a portion thermally pressed has conductivity such that the individual electrodes of the second substrate S2 and the micro LEDs 100 are electrically connected with each other.

Although not illustrated in the drawings, the first substrate S1 may be embodied by an anisotropic conductive anodic oxide film. In this case, a micro LED semi-finished product module according to an embodiment of the present invention is manufactured to be individually bonded to the second substrate S2. The semi-finished product module is modularized by mounting the multiple micro LEDs 100 on the anisotropic conductive anodic oxide film (not illustrated). Here, the second substrate S2 may be embodied by a circuit board.

The anodic oxide film is a film formed by anodizing a metal that is a base material, and pores are formed in a process of forming the anodic oxide film by anodizing the metal. For example, in a case that the base metal is aluminum (Al) or an aluminum alloy, the anodization of the base material forms the anodic oxide film consisting of anodized aluminum (Al₂O₃) on a surface of the base material. The anodic oxide film formed as described above includes a barrier layer in which pores are not formed and a porous layer in which the pores are formed inside. The barrier layer is positioned on top of the base material and the porous layer is positioned on top of the barrier layer. After removing the base material on which the anodic oxide film having the barrier layer and the porous layer is formed, only anodic oxide film consisting of anodized aluminum (Al₂O₃) remains. In addition, after removing the barrier layer, the anodic oxide film has the pores extending from top to bottom longitudinally and having a regular arrangement with a uniform diameter. An internal width of the pores has a size of several nanometers to several hundred nanometers.

The pores are formed independently. Thus, when a conductive material is filled in each of the pores, a conductive material filled in the respective pores does not communicate with adjacent pores and exists independently. In other words, since the pores of the anodic oxide film are vertically formed and spaced apart from each other, the conductive material filled in the pores is also vertically formed and spaced apart from adjacent one.

As described above, the conductive material is filled in the pores of the anodic oxide film such that the anisotropic conductive anodic oxide film is formed, which is conductive in the vertical direction and non-conductive in the horizontal direction.

The micro LEDs 100 are mounted on the anisotropic conductive anodic oxide film formed as described above such that the micro LED semi-finished product module M is constituted. The anisotropic conductive anodic oxide film is provided between the micro LEDs 100 and the second substrate S2 to electrically connect therebetween.

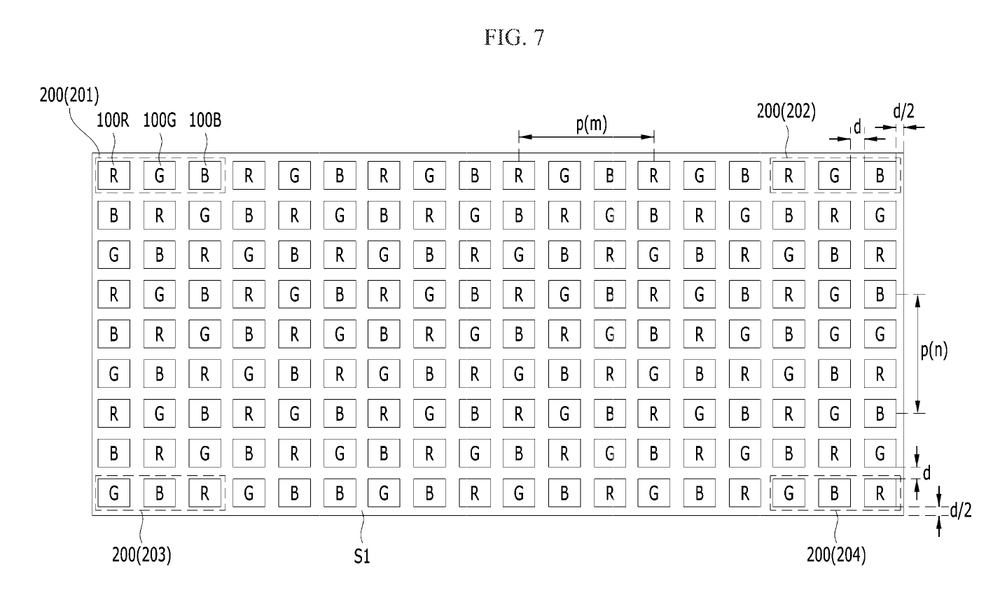

FIGS. 7 to 11 are views each illustrating the micro LEDs 100 arranged in the micro LED semi-finished product module M according to the embodiment of the present invention. Although the horizontal cross section of the micro LEDs 100 illustrated in FIGS. 7 to 11 is quadrangular, it is obvious that the horizontal cross section of the micro LEDs 100 may be circular.

As illustrated in FIG. 7, a red micro LED 100R, a green micro LED 100G, and a blue micro LED 100B are arranged in a one-dimensional array to form unit pixels 200. Here, an arrangement order of a unit pixel 202 positioned at the first row and the Mth column is the same as an arrangement order of a unit pixel 201 positioned at the first row and the first column, and an arrangement order (GBR) of a unit pixel 203 positioned at the Nth row and the first column and an arrangement order of a unit pixel 204 positioned at the Nth row and the Mth column are the arrangement order of the unit pixel 201 positioned at the first row and the second column, wherein M is an integer of 2 or more, and N is a multiple of 3.

For example, referring to FIG. 7, the arrangement order of the unit pixel 201 positioned at the first row and the first column is such that the red micro LED 100R, the green micro LED 100G, and the blue micro LED 100B are arranged in order. Unit pixels 200 having the same arrangement order with the above-described arrangement order are repeatedly disposed by an integer multiple in the column direction (horizontal direction), whereby a unit pixel positioned at the first row and the sixth column, which is the last column, has the same arrangement order as the unit pixel 201 positioned at the first row and the first column does.

An arrangement order of a unit pixel 200 positioned at the second row and the first column is such that the blue micro LED 100B, the red micro LED 100R, and the green micro LED 100G are arranged in order, and an arrangement order of a unit pixel 200 positioned at the third row and the first column is such that the green micro LED 100G, the blue micro LED 100B, and the red micro LED 100R are arranged in order.

An arrangement order of a unit pixel 203 positioned at the ninth row and the first column, which is the last row in the first column, is the arrangement order of the unit pixel 201 positioned at the first row and the second column, and an arrangement order of a unit pixel 204 positioned at the ninth row and the sixth column, which is the last row and the last column, is the arrangement order of the unit pixel 201 positioned at the first row and the second column. According to the above configuration, even when the multiple semi-finished product modules M are arranged adjacent to each other on the second substrate S2, it is possible to implement unit pixels in the horizontal and vertical directions with respect to a specific micro LED 100.

The micro LEDs 100 are arranged at constant pitch distances p(m) and p(n). When referring a distance between adjacent micro LEDs 100 to ‘d’, a spacing distance between the micro LEDs 100 located at the outermost edge of the semi-finished product modules M is equal to or less than half of the spacing distance d between the micro LEDs 100. According to the above configuration, even when the multiple semi-finished product modules M are disposed adjacent to each other on the second substrate S2, it is possible to prevent that pixels are spaced apart from each other at the bonding region between the semi-finished product modules M.

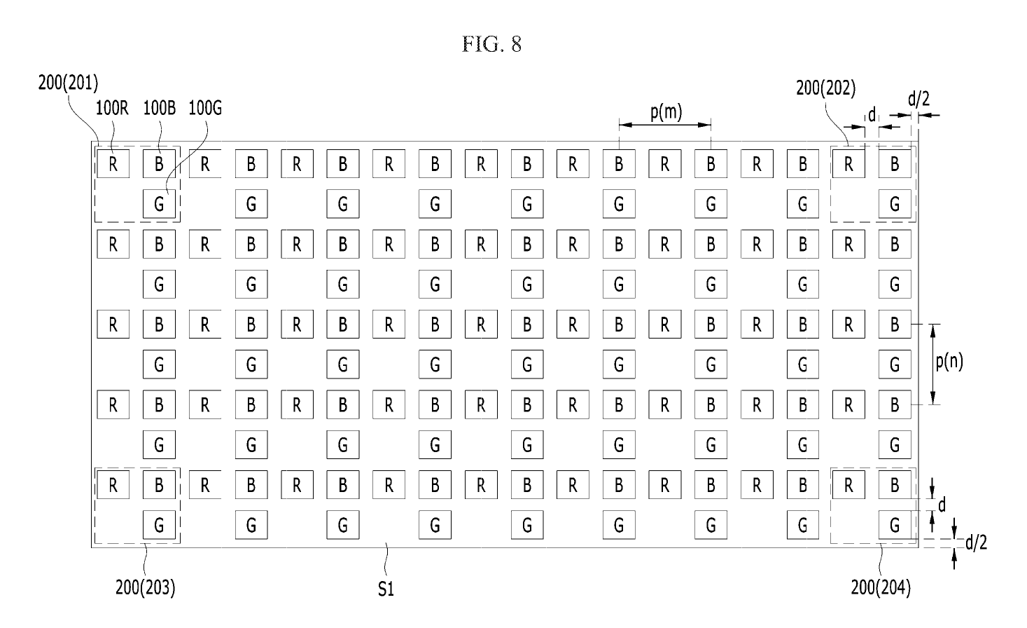

FIGS. 8 to 11 illustrate unit pixels 200 in which a red micro LED 100R, a green micro LED 100G, and a blue micro LED 100B are arranged in a two-dimensional array, wherein the unit pixels 200 are disposed in an N by M matrix.

As illustrated in FIG. 8, a unit pixel 200 has a two-dimensional array in which the blue micro LED 100B is on the right side of the red micro LED 100R and the green micro LED 100G is on the bottom side of the blue micro LED 100B.

Unit pixels 200 having the same arrangement order with an arrangement order of a unit pixel 201 positioned at the first row and the first column are repeatedly disposed in an integer multiple in the column direction (horizontal direction) and the row direction. For example, a unit pixel 202 positioned at the first row and the ninth column, which is the last column in the first row, has the same arrangement order as the unit pixel 201 positioned at the first row and the first column does. A unit pixel 203 positioned at the fifth row and the first column, which is the last row in the first column, has the same arrangement order as the unit pixel 201 positioned at the first row and the first column does. In addition, a unit pixel 204 positioned at the fourth row and the sixth column, which is the last row and the last column, has the same arrangement order as the unit pixel 201 positioned at the first row and the first column does. According to the above configuration, even when the multiple semi-finished product modules M are disposed adjacent to each other on the second substrate S2, it is possible to obtain an entire distribution on the second substrate S2 same as the distribution of the unit pixels of the semi-finished product modules M.

In addition, the micro LEDs 100 are arranged at constant pitch distances p(m) and p(n). When referring a distance between adjacent micro LEDs 100 to ‘d’, a spacing distance between the micro LEDs 100 located at the outermost edge of the semi-finished product modules M is equal to or less than half of the spacing distance d between the micro LEDs 100. According to the above configuration, even when the multiple semi-finished product modules M are disposed adjacent to each other on the second substrate S2, it is possible to prevent that pixels are spaced apart from each other at the bonding region between the semi-finished product modules M.

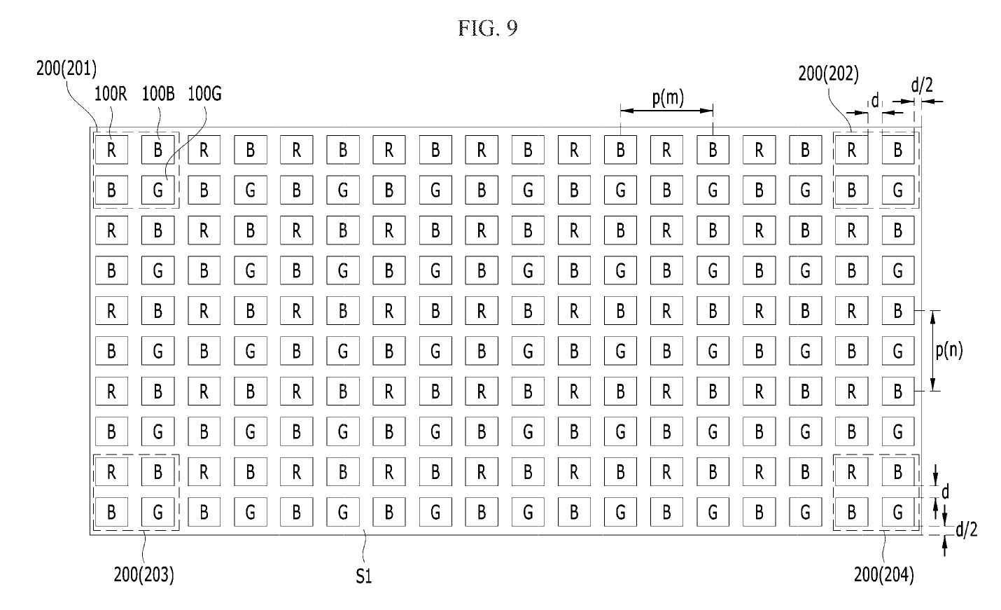

FIGS. 8 and 9 have a difference in the number of micro LEDs 100 constituting the unit pixel 200. As illustrated in FIG. 9, a unit pixel 200 has a two-dimensional array in which a blue micro LED 100B is on the right side of a red micro LED 100R, a green micro LED 100G is on the bottom side of the blue micro LED 100B, and another blue micro LED 100B is on the bottom side of the red micro LED 100R.

In the unit pixel 200 illustrated in FIG. 9, two blue micro LEDs B are disposed to improve the color space in consideration that the human spectral sensitivity to color is generally weak at short wavelengths.

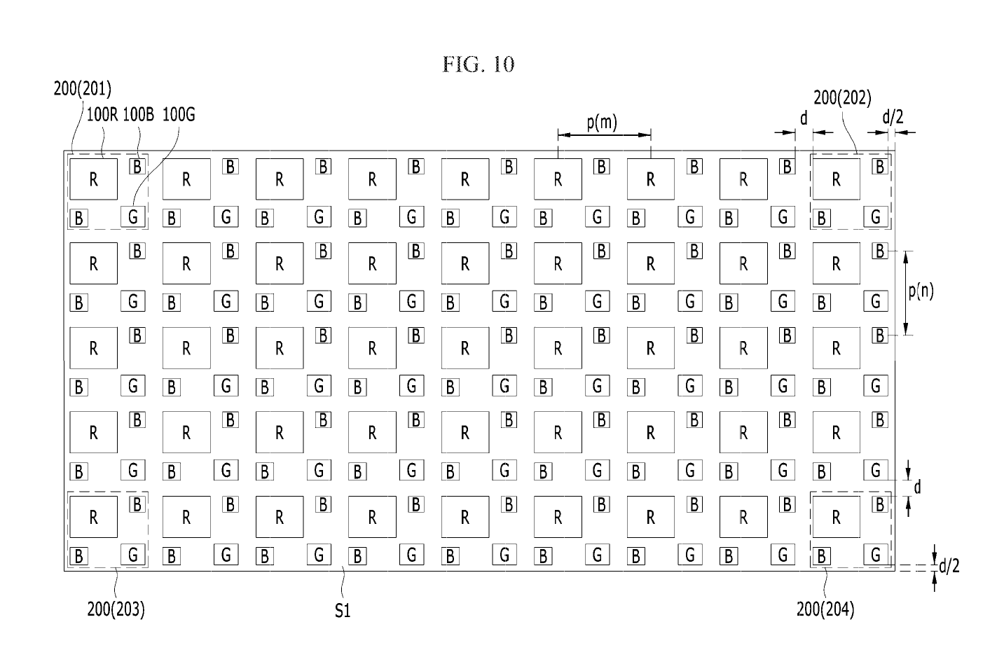

An arrangement order of the micro LEDs 100 constituting a unit pixel 200 illustrated in FIG. 10 is the same as the arrangement order of the micro LEDs 100 constituting the unit pixel 200 illustrated in FIG. 9. FIGS. 9 and 10 have a difference in size of the micro LEDs 100. Considering that the red micro LED 100R has a weaker emitting intensity per area than the blue micro LEDs 100B and the green micro LED 100G, the red micro LED 100R illustrated in FIG. 10 has a larger area than the blue micro LEDs 100B and the green micro LED 100G. In addition, in consideration of the fact that two blue micro LEDs 100B are provided, the green micro LED 100G has a larger area than the blue micro LEDs 100B.

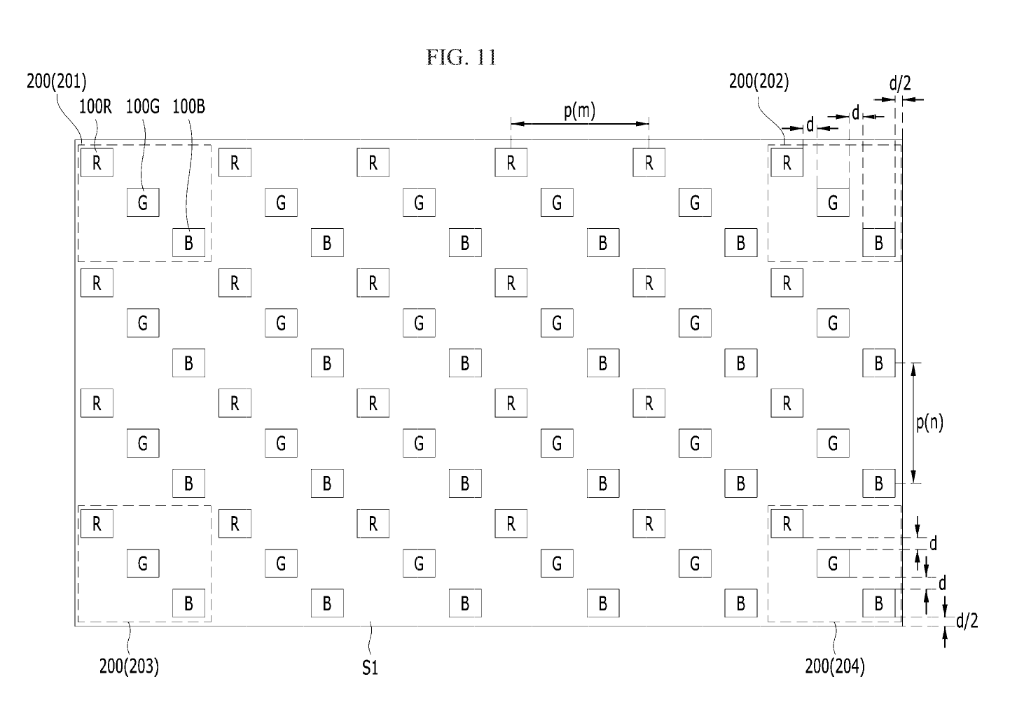

A unit pixel 200 illustrated in FIG. 11 has a two-dimensional array in which a red micro LED 100R, a green micro LED 100G, and a blue micro LED 100B are arranged in order in the diagonal direction.

As illustrated in FIG. 11, unit pixels 200 having the same arrangement order with an arrangement order of a unit pixel 201 positioned at the first row and the first column are repeatedly disposed in an integer multiple in the column direction (horizontal direction) and the row direction. For example, a unit pixel 202 positioned at the first row and the sixth column, which is the last column in the first row, has the same arrangement order as the unit pixel 201 positioned at the first row and the first column does. A unit pixel 203 positioned at the fourth row and the first column, which is the last row in the first column, has the same arrangement order as the unit pixel 201 positioned at the first row and the first column does. In addition, a unit pixel 204 positioned at the fourth row and the sixth column, which is the last row and the last column, has the same arrangement order as the unit pixel 201 positioned at the first row and the first column does. According to the above configuration, even when the multiple semi-finished product modules M are disposed adjacent to each other on the second substrate S2, it is possible to obtain an entire distribution on the second substrate S2 same as the distribution of the unit pixels of the semi-finished product modules M.

In addition, the micro LEDs 100 are arranged at constant pitch distances p(m) and p(n). When referring a distance between adjacent micro LEDs 100 to ‘d’, a spacing distance between the micro LEDs 100 located at the outermost edge of the semi-finished product modules M is equal to or less than half of the spacing distance d between the micro LEDs 100. According to the above configuration, even when the multiple semi-finished product modules M are disposed adjacent to each other on the second substrate S2, it is possible to prevent that pixels are spaced apart from each other at the bonding region between the semi-finished product modules M.

As described above, the present invention has been described with reference to the embodiments. However, those skilled in the art will appreciate that various modifications, additions and substitutions are possible, without departing from the scope and spirit of the invention as disclosed in the accompanying claims.

What is claimed:

1. A micro LED semi-finished product module manufactured to be individually bonded to a wiring board,
wherein the semi-finished product module is modularized by mounting multiple micro LEDs on a circuit board.

2. The semi-finished product module of claim 1, wherein the semi-finished product module is manufactured such that each of the micro LEDs of each semi-finished product module is individually driven by the wiring board to which the each micro LED semi-finished product module is bonded.

3. The semi-finished product module of claim 1, wherein the semi-finished product module is manufactured such that each semi-finished product module is individually driven by the wiring board to which the each micro LED semi-finished product module is bonded.

4. The semi-finished product module of claim 1, wherein the semi-finished product module is manufactured such that all of the micro LEDs are driven by the wiring board to which the micro LED semi-finished product module is bonded.

5. The semi-finished product module of claim 1, wherein the circuit board is provided with a thin-film transistor (TFT) circuit.

6. A micro LED semi-finished product module manufactured to be individually bonded to a circuit board,
wherein the semi-finished product module is modularized by mounting multiple micro LEDs on an anisotropic conductive film.

7. A micro LED semi-finished product module manufactured to be individually bonded to a circuit board,
wherein the semi-finished product module is modularized by mounting multiple micro LEDs on an anisotropic conductive anodic oxide film.

8. The semi-finished product module of any one of claims 1, 6, and 7, wherein the semi-finished product module has a one-dimensional array in which a red micro LED, a green micro LED, and a blue micro LED are arranged to form unit pixels,
wherein a unit pixel positioned at the first row and the Mth column has the same arrangement order as a unit pixel positioned at the first row and the first column does, and
an arrangement order of a unit pixel positioned at the Nth row and the first column and an arrangement order of a unit pixel positioned at the Nth row and the Mth column are the arrangement order of the unit pixel positioned at the first row and the second column,
wherein M is an integer of 2 or more, and N is a multiple of 3.

9. The semi-finished product module of any one of claims 1, 6, and 7, wherein the semi-finished product module has a two-dimensional array in which a red micro LED, a green micro LED, and a blue micro LED are arranged to form unit pixels, and
the unit pixels are arranged in an N by M matrix.

10. The semi-finished product module of any one of claims 1, 6, and 7, wherein a distance between the micro LEDs located at the outermost edge of the semi-finished product module is equal to or less than half of a distance between the micro LEDs.
